(19) United States
(12) Patent Application Publication
(10) Pub. No.: US 2020/0058330 A1
(43) Pub. Date: Feb. 20, 2020

(54) CLIENT LATENCY-AWARE MICRO-IDLE MEMORY POWER MANAGEMENT

(71) Applicant: QUALCOMM INCORPORATED, SAN DIEGO, CA (US)

(72) Inventors: PAWAN CHHABRA, BANGALORE (IN); VENKATA DEVARASETTY, HYDERABAD (IN); MAYANK GUPTA, BANGALORE (IN); MAHESHWAR THAKUR SINGH, HYDERABAD (IN); HARSHIT TIWARI, SAN DIEGO, CA (US)

(21) Appl. No.: 16/103,319

(22) Filed: Aug. 14, 2018

(51) Int. Cl. G11C 5/14; G06F 1/32; G11C 11/4074; G11C 11/4076; G11C 7/20

(52) U.S. Cl. CPC G11C 5/14; G06F 1/3225; G06F 1/3275; G11C 2207/2227; G11C 11/4076; G11C 7/20; G11C 2207/2272; G11C 11/4074

(57) ABSTRACT

Systems and methods are disclosed for providing micro-idle memory power management. One embodiment of a method comprises receiving and storing an exit latency vote from each of a plurality of memory subsystems on a system on chip electrically coupled to a system memory. In response to a micro-idle memory state in which each of the memory subsystems are idle, a minimum exit latency value from the plurality of exit latency votes is determined. One of a plurality of system memory modes is selected which has a micro-idle sleep time that meets the minimum exit latency value while minimizing system memory power consumption. The selected system memory mode is initiated.

### DESCRIPTION OF THE RELATED ART

Portable communication devices (e.g., cellular telephones, smart phones, tablet computers, portable game consoles, wearable devices, and other battery-powered devices) and other computing devices continue to offer an ever-expanding array of features and services, and provide users with unprecedented levels of access to information, resources, and communications. To keep pace with these service enhancements, such devices have become more powerful and more complex. Portable communication devices now commonly include a system on chip (SoC) comprising a plurality of processing devices embedded on a single substrate, which may read data from and store data in an off-chip or external system memory comprising volatile memory (e.g., double data rate (DDR) dynamic random access memory (DRAM)) via a high-speed bus.

A significant factor in the success of SoC designs is the ability to deliver efficient access to the external system memory, which is typically shared and services the SoC processing devices with varying bandwidth and latency requirements. In addition to providing data to the on-chip memory clients, there is considerable demand to manage large amounts of data while operating in a power efficient manner. To minimize power consumption, such devices may implement micro-idle power management techniques. The term “micro idle” refers to a transient timing window in which all the SoC memory clients are idle and do not require memory bandwidth. In conventional portable communication devices, the micro idle window may range from approximately 1 to hundreds of microseconds (us).

As known in the art, the micro idle window may occur during intra-frame processing and, therefore, presents in many operational use cases, such as, for example, audio playback, video decode, voice calls, static display, etc. The micro idle window presents an opportunity to save DDR controller, physical layer (PHY), and DRAM power consumption. Existing solutions for providing micro-idle power management typically employ one or two levels of firmware (e.g., SoC power management microcontroller firmware, DDR subsystem (DDRSS) local microcontroller firmware). Firmware-based solutions may result in high entry/exit overhead due to the various handshakes with software/hardware associated with each of the SoC memory clients, which may significantly limit the opportunities to save micro-idle power consumption in certain use cases.

Accordingly, there is a need for improved systems and methods for providing micro-idle power consumption.

### SUMMARY OF THE DISCLOSURE

Systems and methods are disclosed for providing micro-idle memory power management. One embodiment of a method comprises receiving and storing an exit latency vote from each of a plurality of memory subsystems on a system on chip electrically coupled to a system memory. In response to a micro-idle memory state in which each of the memory subsystems are idle, a minimum exit latency value from the plurality of exit latency votes is determined. One of a plurality of system memory modes is selected which has a micro-idle sleep time that meets the minimum exit latency value while minimizing system memory power consumption. The selected system memory mode is initiated.

An embodiment of a micro-idle memory power management system comprises a double data rate (DDR) memory electrically coupled to a system on chip (SoC). The SoC comprises a plurality of memory subsystems, a DDR memory controller, and a micro-idle power management hardware module. The micro-idle power management hardware module comprises one or more hardware registers, a comparator, and a finite state machine. The one or more hardware registers are configured to receive and store an exit latency vote from each of the plurality of memory subsystems. The comparator is in communication with the one or more hardware registers and configured to determine, in response to a micro-idle memory state in which each of the plurality of memory subsystems are idle, a minimum exit latency value from the plurality of exit latency votes. The finite state machine comprises a plurality of memory states and is configured to receive the minimum exit latency and, in response, select one of the plurality of memory states having a micro-idle sleep time that meets the minimum exit latency value while minimizing DDR memory power consumption.

### BRIEF DESCRIPTION OF THE DRAWINGS

In the Figures, like reference numerals refer to like parts throughout the various views unless otherwise indicated. For reference numerals with letter character designations such as “102A” or “102B”, the letter character designations may differentiate two like parts or elements present in the same Figure. Letter character designations for reference numerals may be omitted when it is intended that a reference numeral to encompass all parts having the same reference numeral in all Figures.

FIG. 1 is a block diagram of an embodiment of a system for providing client latency-aware micro-idle power management.

FIG. 2 illustrates an exemplary micro-idle timing diagram.

FIG. 3 is a flowchart illustrating an embodiment of a method implemented in the system of FIG. 1 for providing client latency-aware micro-idle power management.

FIG. 4 is a block diagram illustrating an embodiment of the client latency-aware micro-idle power manager hardware system of FIG. 1.

FIG. 5 is a data structure illustrating an exemplary mapping of exit latency client tolerances to corresponding micro-idle power states.

FIG. 6 illustrates exemplary micro-idle sleep time ranges for the exit latency client tolerances in FIG. 5.

FIG. 7 is a combined block/flow diagram illustrating an embodiment of client latency-aware micro-idle power management in an exemplary use case.

FIG. 8 is a block diagram of an exemplary embodiment of a portable communication device for incorporating the system of FIG. 1.

### DETAILED DESCRIPTION

The word “exemplary” is used herein to mean “serving as an example, instance, or illustration.” Any aspect described herein as “exemplary” is not necessarily to be construed as preferred or advantageous over other aspects.

In this description, the term “application” may also include files having executable content, such as: object code, scripts, byte code, markup language files, and patches. In addition, an “application” referred to herein, may also include files that are not executable in nature, such as documents that may need to be opened or other data files that need to be accessed.

The term “content” may also include files having executable content, such as: object code, scripts, byte code, markup language files, and patches. In addition, “content” referred to herein, may also include files that are not executable in nature, such as documents that may need to be opened or other data files that need to be accessed.

As used in this description, the terms “component,” “database,” “module,” “system,” and the like are intended to refer to a computer-related entity, either hardware, firmware, a combination of hardware and software, software, or software in execution. For example, a component may be, but is not limited to being, a process running on a processor, a processor, an object, an executable, a thread of execution, a program, and/or a computer. By way of illustration, both an application running on a computing device and the computing device may be a component. One or more components may reside within a process and/or thread of execution, and a component may be localized on one computer and/or distributed between two or more computers. In addition, these components may execute from various computer readable media having various data structures stored thereon. The components may communicate by way of local and/or remote processes such as in accordance with a signal having one or more data packets (e.g., data from one component interacting with another component in a local system, distributed system, and/or across a network such as the Internet with other systems by way of the signal).

In this description, the terms “communication device,” “wireless device,” “wireless telephone”, “wireless communication device,” and “wireless handset” are used interchangeably. With the advent of third generation (“3G”), fourth generation (“4G”), fifth generation (“5G”) and other wireless technology, greater bandwidth availability has enabled more portable computing devices with a greater variety of wireless capabilities.

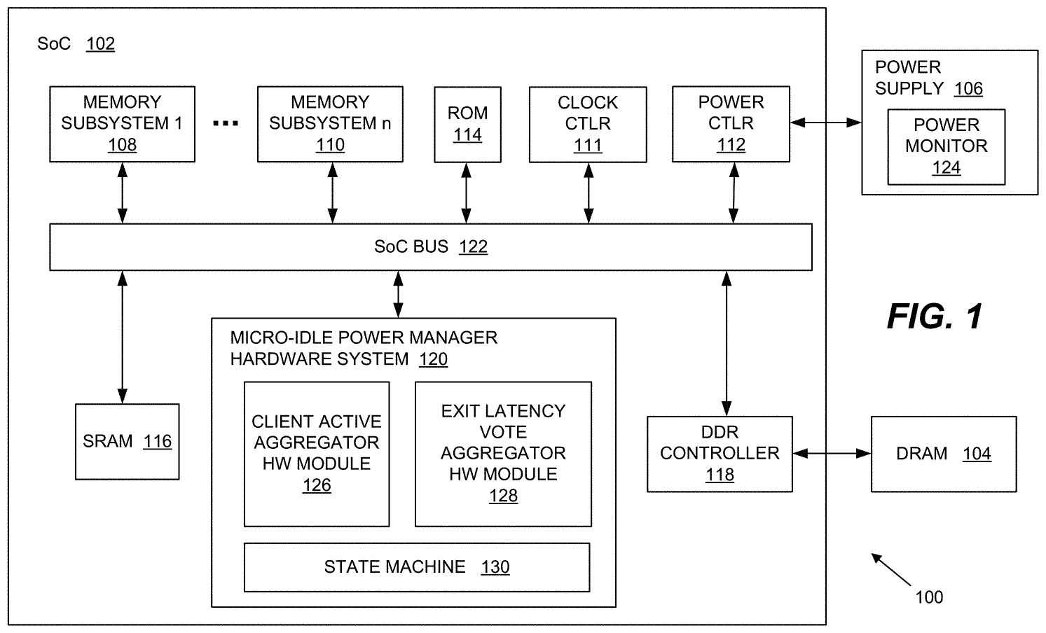

FIG. 1 illustrates an embodiment of a system 100 for providing client latency-aware micro-idle power management. The system 100 comprises a system on chip (SoC) 102 electrically coupled to an external system memory via a memory bus. In the embodiment of FIG. 1, the external system memory comprises volatile memory, such as, for example, dynamic random access memory (DRAM) 104. DRAM 104 may comprise a double data rate (DDR) synchronous DRAM configured to operate at two or more dynamically selectable frequencies. The memory bus, which electrically couples the SoC 102 to DRAM 104, may comprise a DDR bus supporting any of the following: low power DDR (LPDDR), LPDDR2, LPDD3, DDR2, DDR3, etc. It should be appreciated that system 100 may be incorporated in various types of computing devices, including a personal computer, a workstation, a server, a laptop computer, a gaming console, or a portable communication device (PCD), such as a cellular telephone, a smartphone, a portable digital assistant (PDA), a portable game console, a tablet computer, a fitness computer, and a wearable device (e.g., a sports watch, a fitness tracking device, etc.) or other battery-powered devices with a wireless connection or link.

As illustrated in FIG. 1, SoC 102 comprises various on-chip components electrically coupled via SoC bus 122. In the embodiment of FIG. 1, SoC 102 comprises a plurality of memory clients or memory subsystems 1-n. The memory subsystems 108 and 110 may comprise for example, a central processing unit (CPU) subsystem comprising one or more cores, a graphics processing unit (GPU) subsystem comprising one or more cores, a digital signal processor (DSP) subsystem, a modem subsystem, or any other SoC processing device comprising a memory subsystem configured to read/write data to/from DRAM 104. SoC 102 may further comprise static random access memory (SRAM) 116, read only memory (ROM) 114, a DDR controller 118, a power controller 112, and a clock controller 111 interconnected via SoC bus 122.

Power controller 112 is electrically coupled to a power supply 106 via a power control bus, which comprises a power monitor 124 configured to measure energy usage associated with the SoC 102 and the DRAM 104 and, thereby, monitor device power consumption.

Clock controller 111 is responsible for generation, control and distribution of clocks to all the SoC subsystems and blocks. In an exemplary embodiment, clock controller 111 comprises shared Phase Locked Loops (PLLs) and Glitch-Free Clock Mux/Gate for each clock branch.

DDR controller 118 is configured to manage communication between SoC 102 and DRAM 104, including read and/or write transactions from memory subsystems 1-n residing on SoC 102.

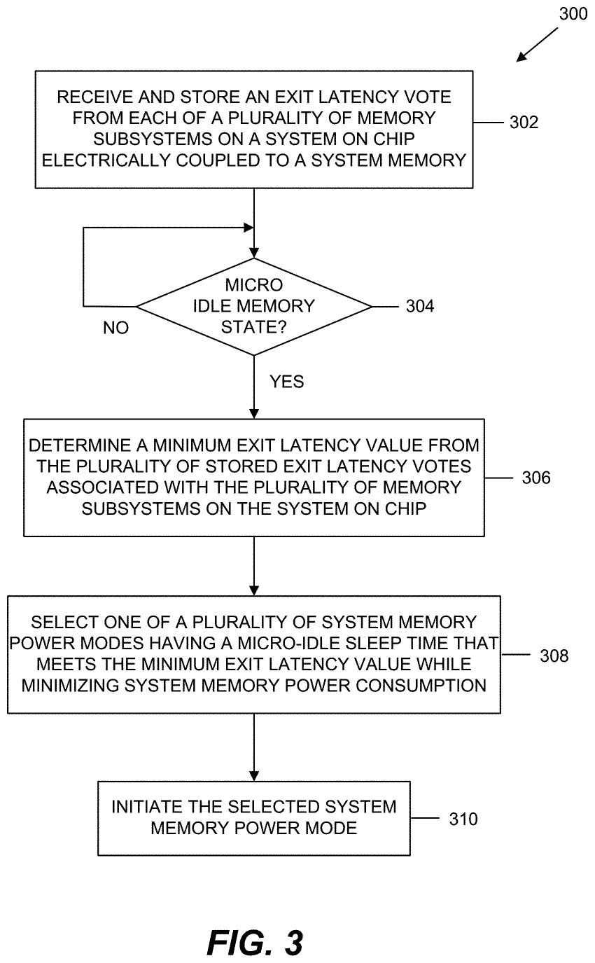

As further illustrated in FIG. 1, SoC 102 further comprises a specially-configured micro-idle power manager hardware system 120, which is configured to provide client latency-aware micro-idle power management. The architecture, operation, and/or functionality of micro-idle power manager hardware system 120 are described below in more detail with reference to FIGS. 3-7. As an introductory matter, it should be appreciated that micro-idle power manager hardware system 120 is configured to receive input(s) from memory subsystems 1-n. The input(s) may be related to, for example, client-specific exit latency and/or micro-idle sleep time constraints. In response to the input(s) received from memory subsystems 1-n, micro-idle power manager hardware system 120 may determine one of a plurality of memory power states to initiate during a micro-idle window, which meets sleep time or exit latency requirements of the most aggressive memory subsystem. In this manner, micro-idle power manager hardware system 120 may provide increased power saving during the micro-idle window by guaranteeing minimum entry/exit delay overhead as compared to existing firmware-based solutions.

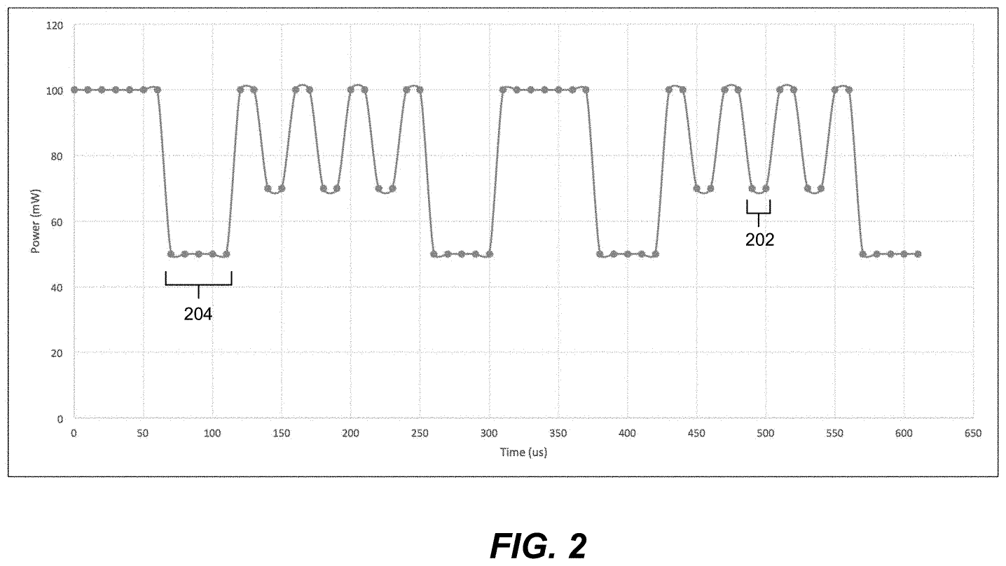

In the embodiment of FIG. 1, micro-idle power manager hardware system 120 comprises a finite state machine 120, a client active aggregator hardware module 126, and an exit latency vote aggregator hardware module 128. Client active aggregator hardware module 126 comprises the hardware logic for monitoring whether memory subsystems 1-n are active (i.e., requiring memory bandwidth) or inactive (i.e., not requiring memory bandwidth). As illustrated in FIG. 2, a micro-idle window 202 may occur when each of memory subsystems 1-n are determined to be inactive. In the exemplary embodiment of FIG. 2, it should be appreciated that micro-idle window 202 may correspond to an intraframe idle state (i.e., within a processing frame), whereas a macro-idle window 204 may correspond to an interframe idle state (i.e., across a plurality of processing frames).

Exit latency vote aggregator hardware module 128 comprises the hardware logic for receiving data related to the ongoing exit latency or micro-idle sleep time requirements of memory subsystems 1-n during operation of system 100. Exit latency vote aggregator hardware module 128 is configured to compute a minimum value (MIN) of the plurality of exit latency votes programmed in the respective CSRs for each memory subsystem. In an exemplary embodiment, exit latency vote aggregator hardware module 128 may be implemented in hardware with one or more comparators and multiplexers.

Finite state machine 120 comprises combinational logic for supporting a plurality of memory power states or modes for controlling operation of the off-chip system memory (e.g., DRAM 104) during a micro-idle window. When client active aggregator hardware module 126 determines a micro-idle window in which memory subsystems 1-n are all inactive, micro-idle power manager hardware system 120 selects the lowest available memory power state based on the current exit latency or micro-idle sleep time requirements of memory subsystems 1-n. For example, micro-idle power manager hardware system 120 may determine the deepest power state possible for DDR controller 118, associated DDR physical layer (PHY), and DRAM 104 that minimizes power consumption while meeting a minimum exit latency requirement of the most aggressive memory subsystem 1-n.

FIG. 3 illustrates an embodiment of a method 300 implemented in the system 100 for providing client latency-aware micro-idle power management. At block 302, micro-idle power manager hardware system 120 may receive and store an exit latency value from each of a plurality of memory subsystems on SoC 102. In an embodiment, the memory subsystems 1-n may comprise a software driver for transmitting the corresponding client's exit latency value via a hardware interface to micro-idle power manager hardware system 120. The client-specific exit latency values may be stored in one or more hardware registers. At decision block 304, a micro-idle memory state may occur or be initiated (e.g., client active aggregator hardware module 126 determining that all of memory subsystems 1-n will be inactive). In response to the micro-idle memory state, at block 306, micro-idle power manager hardware system 120 may determine a minimum exit latency value from the plurality of exit latency values stored in the hardware register(s). At block 308, micro-idle power manager hardware system 120 selects one of a plurality of system memory power modes supported by finite state machine 130. The selected system memory power mode may have a predetermined micro-idle sleep time that meets the minimum exit latency value while minimizing system memory power consumption. At block 310, micro-power manager hardware system 120 initiates the selected system memory power mode during the micro-idle window.

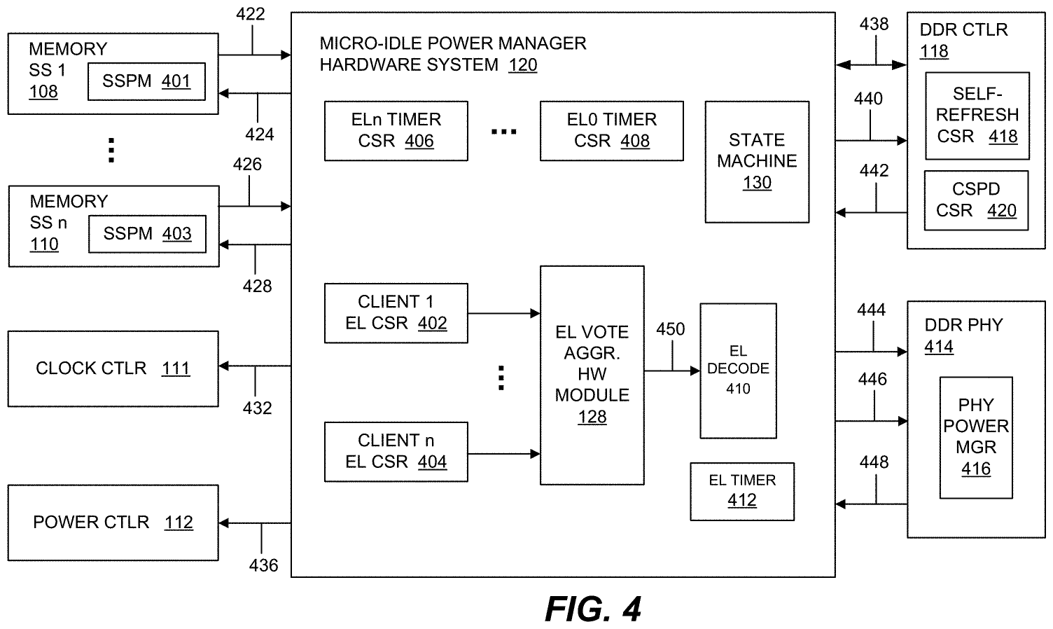

FIG. 4 illustrates an embodiment of micro-idle power manager hardware system 120. In the embodiment of FIG. 4, micro-idle power manager hardware system 120 supports hardware interfaces with memory subsystems 1-n, clock controller 111, power switch controller 112, DDR controller 118, and DDR physical layer (PHY) 414. Memory subsystem 108 may be electrically coupled to micro-idle power manager hardware system 120 via hardware interfaces 422 and 424. Memory subsystem 110 may be electrically coupled to micro-idle power manager hardware system 120 via hardware interfaces 426 and 428. A subsystem power manager module 401 associated with memory subsystem 108 may send a client_0 DDR_vote signal to micro-idle power manager hardware system 120, via hardware interface 422, when the client is active/inactive. A subsystem power manager module 403 associated with memory subsystem 110 may send a client n DDR_vote signal to micro-idle power manager hardware system 120, via hardware interface 426, when the client is active/inactive.

Micro-idle power manager hardware system 120 may send a DDR ready signal to memory subsystems 108 and 110, via interfaces 424 and 428, respectively, to indicate when DDR controller 118 and PHY 414 are out of a sleep state. Micro-idle power manager hardware system 120 may send a root clock_gate_enable signal to clock controller 111, via hardware interface 432, indicating that root clock gating is enabled to gate off DDR controller 118 and PHY 414 clock branches. Handshake signals used for controlling power switches (e.g., pg_en/ack) may be sent to power controller 112, via hardware interface 436, indicating that micro-idle power manager hardware system 120 is in an Always ON domain.

DDR controller 118 may be electrically coupled to micro-idle power manager hardware system 120 via hardware interfaces 438, 440, and 442. Hardware interface 438 comprises a control and status register (CSR) programming bus for enabling the system 100 to enter one of a plurality of power states that meets the selected minimum exit latency value of the memory subsystems 1-n. As illustrated in FIG. 4, DDR controller 118 may comprise a self-refresh power down CSR 418 and a clock stop power down (CSPD) CSR 420 for enabling micro-idle power manager hardware system 120 to initiate a self-refresh state and a CSPD state, respectively. Hardware interface 440 may be used to provide a CSR value to the corresponding CSRs 418 and 420. Hardware interface 442 may be used to provide a status signal from DDR controller 118 to micro-idle power manager hardware system 120, which may indicate outstanding DRAM command(s).

DDR PHY 414 may be electrically coupled to micro-idle power manager hardware system 120 via hardware interfaces 444, 446, and 448. It should be appreciated that interfaces 444, 446, and 448 may drive low power post controller handshake and EL values. For example, interface 444 may enable micro-idle power manager hardware system 120 to send a low power request signal (lp req) to PHY power manager 416. Interface 448 may enable micro-idle power manager hardware system 120 to receive acknowledge signal(s) (lp_ack) from PHY power manager 416. Interface 446 may enable micro-idle power manager hardware system 120 to send a low power wake-up signal (lp wakeup) to PHY power manager 416.

As mentioned above, micro-idle power manager hardware system 120 is configured to receive ongoing client-specific exit latency values or votes from each of the memory subsystems. In the embodiment of FIG. 4, micro-idle power manager hardware system 120 comprises a dedicated control and status register (CSR) for each memory subsystem, which is used to store the corresponding exit latency value. CSR 402 may store an exit latency value for memory subsystem 108. CSR 404 may store an exit latency value for memory subsystem 110. CSRs 402 and 404 may be electrically coupled to exit latency vote aggregator hardware module 128, which is configured to determine which of the stored values comprises a minimum exit latency value. Exit latency vote aggregator hardware module 128 may be electrically coupled to a decode hardware module 410 via an interface 450. Decode hardware module 410 takes the aggregated exit latency value and generates decoded controls for state machine 130 and exit latency timer 412. Based on the respective control from the decoder block 410, EL timer 412 may be loaded with corresponding exit latency values. It should be appreciated that exit latency timer 412 may comprise CSR(s), which are programmed to map exit latency decoded values to exit latency values.

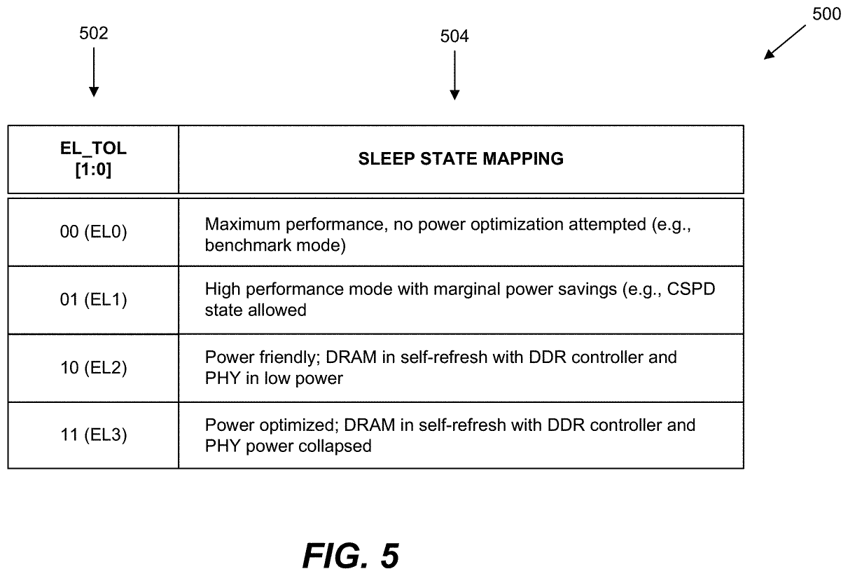

FIG. 5 illustrates an exemplary mapping of client-specific exit latency votes to corresponding memory power modes. As mentioned above, each of the memory power modes correspond to one of the states defined by state machine 130. Column 502 comprises one of a plurality of predetermined exit latency votes or tolerance values that may be generated by memory subsystems 1-n and transmitted to micro-idle power manager hardware system 120. Column 504 comprises the memory power mode associated with the corresponding exit latency vote in column 502. The predetermined exit latency votes may comprise a bit sequence EL_TOL [1:0]. The embodiment of FIG. 5 comprises four exit latency votes. A first exit latency vote (EL0) comprises the value “00”, which is mapped to a first memory power mode—a maximum performance mode (e.g., benchmark mode), in which no power optimization is attempted. A second exit latency vote (EL1) comprises the value “01”, which is mapped to a second memory power mode—a high-performance mode with marginal power savings. In an embodiment, the marginal power savings provided by the second memory power mode may involve a clock stop power down (CSPD) via, for example, CSR 420 (FIG. 4). A third exit latency vote (EL3) comprises the value “10”, which is mapped to a third memory power mode—a “power friendly” mode. In an embodiment, the power friendly mode may comprise placing DRAM 104 in a self-refresh mode (e.g., via CSR 418—FIG. 4) and powering down DDR controller 118 and/or DDY PHY 414. A fourth exit latency vote (EL4) comprises the value “11”, which is mapped to a power optimized mode. In an embodiment, the power optimized mode may comprise placing DRAM 104 in the self-refresh mode and powering down DDR controller 118 and/or DDY PHY 414. Power controller 112 may provide a request/acknowledgement (req/ack) handshake interface to power up/down DDR controller 118.

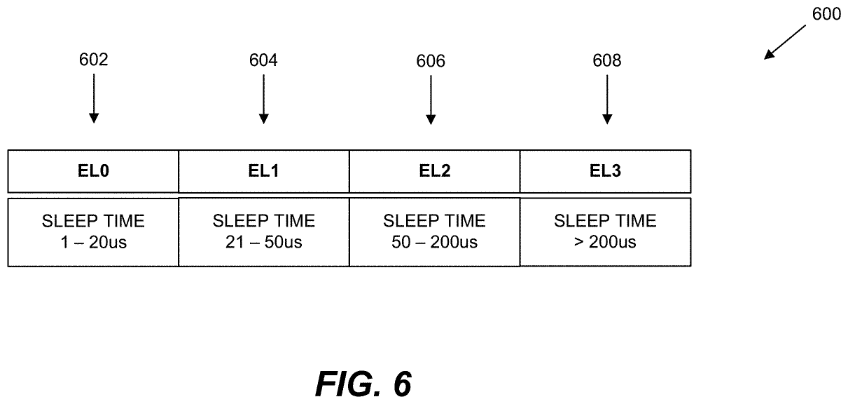

Referring to FIG. 6, it should be appreciated that each of the exit latency votes and associated memory power modes and states of state machine 130 may be mapped to a distinct numerical range for the micro-idle sleep time. In the embodiment of FIG. 6, the first exit latency vote (EL0) for the maximum performance mode (column 602) may be associated with a first micro-idle sleep time of approximately 1-20 microseconds. The second exit latency vote (EL1) for the high-performance mode with marginal power savings (column 604) may be associated with a second micro-idle sleep time of approximately 21-50 microseconds. The third exit latency vote (EL2) for the power friendly mode (column 606) may be associated with a third micro-idle sleep time of approximately 50-200 microseconds. The fourth exit latency vote (EL3) for the power optimized mode (column 606) may be associated with a fourth micro-idle sleep time exceeding approximately 200 microseconds. In this manner, micro-idle power manager hardware system 120 enables the system 100 to realize power savings during micro-idle use cases for which existing solutions are incapable of handling.

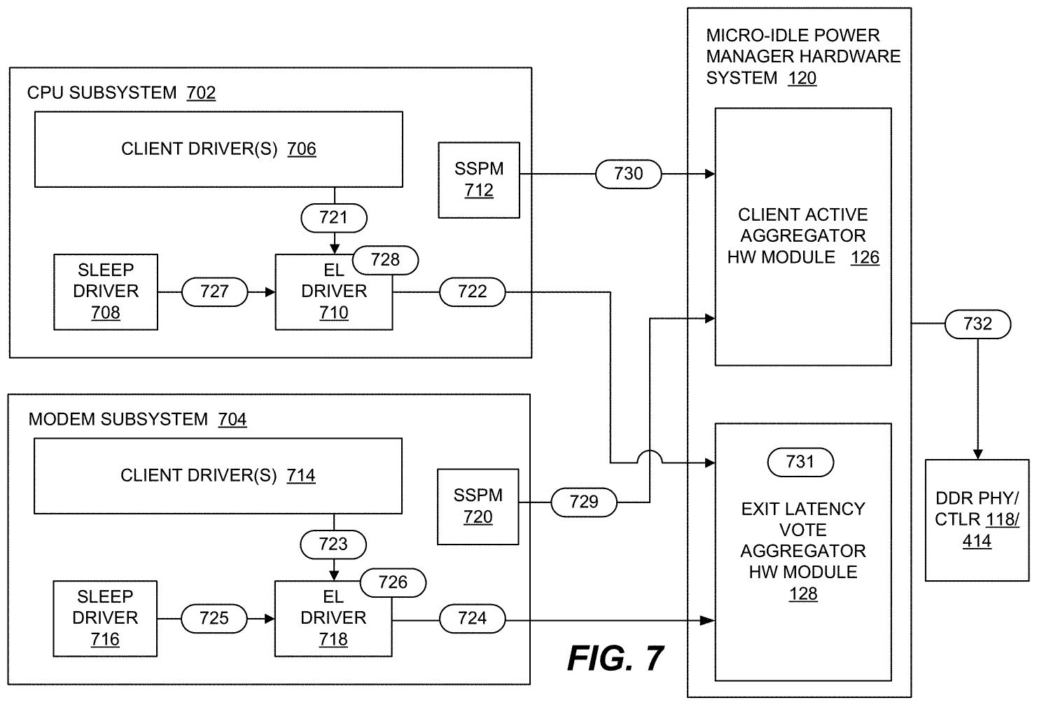

FIG. 7 is a combined block/flow diagram illustrating an embodiment of client latency-aware micro-idle power management in an exemplary use case. The use case illustrated in FIG. 7 comprises a CPU subsystem 702 and a modem subsystem 704. CPU subsystem 702 may comprise a user space and a kernel space. The user space may comprise one or more client drivers 706 defining a system interface for enabling one or more clients to provide exit latency votes to an exit latency driver 710 in a kernel space. The kernel space may further comprise one or more client sleep drivers 708. CPU subsystem 702 may further comprise a subsystem power manager module 712 for communicating with client active aggregator hardware module 126 in micro-idle power manager hardware system 120.

Modem subsystem 704 may comprise one or more client drivers 714 for enabling modem programs or clients to provide exit latency votes to an exit latency driver 718. Modem subsystem 704 may further comprise one or more client sleep drivers 708 and a subsystem power manager module 720 for communicating with client active aggregator hardware module 126 in micro-idle power manager hardware system 120.

Having described the hardware and/or software components of FIG. 7, an exemplary method for providing client latency-aware micro-idle power management in this exemplary use case will be described. The method generally comprises steps 721-732. It should be appreciated that steps 721-732 may be implemented via any combination of software, hardware, and/or firmware. In an exemplary embodiment, steps 721-730 are controlled via software components and steps 731 and 732 are controlled via hardware components in micro-idle power manager hardware system 120.

At block 721, one or more clients associated with CPU subsystem 702 may generate exit latency vote(s) according to their particular latency requirements, tolerances, etc. As illustrated in FIG. 7, the exit latency votes may be generated and/or provided by client driver(s) 706 to exit latency driver(s) 710 via a system interface. At block 722, the exit latencies may be aggregated by exit latency driver 710 and programmed to, for example, a hardware register residing in micro-idle power manager hardware system 120. By way of example, the exit latency vote from CPU subsystem 702 may comprise the third exit latency vote (EL2) having the value “10”, which is mapped to the power friendly mode (FIG. 5).

At block 723, one or more modem clients associated with modem subsystem 704 may generate exit latency vote(s) according to their particular latency requirements, tolerances, etc. The modem client exit latency votes may be generated and/or provided by client driver(s) 714 to exit latency driver 718. At block 724, the modem client exit latencies may be aggregated by exit latency driver 718 and programmed to, for example, another hardware register residing in micro-idle power manager hardware system 120. By way of example, the exit latency vote from modem subsystem 704 may comprise the second exit latency vote (EL1) comprises the value “01”, which is mapped to a high performance mode with marginal power savings (FIG. 5).

At block 725, modem subsystem 704 may go idle, in which case sleep driver 716 updates exit latency requests according to a next wake time. It should be appreciated that this may enable a correct exit latency update in the absence of client votes, as well as in the case where a client exit latency is relatively high but the sleep time is lower. At block 726, exit latency driver 718 in modem subsystem 704 may check whether a current sleep vote is different than a last sleep vote. If the current sleep vote is different than the last sleep vote, exit latency driver 718 may send a new aggregated vote to micro-idle power manager hardware system 120.

At block 727, CPU subsystem 702 may go idle, in which case sleep driver 708 updates exit latency requests according to a next wake time, in a similar manner as modem subsystem 704. At block 728, exit latency driver 710 in CPU subsystem 702 may check whether a current sleep vote is different than a last sleep vote. If the current sleep vote is different than the last sleep vote, exit latency driver 710 may send a new aggregated vote to micro-idle power manager hardware system 120.

At block 729, modem subsystem 704 may go to sleep. For example, subsystem power manager 720 may send a DDR_vote having a value “0” to client active aggregator hardware module 726. At block 730, CPU subsystem 702 may go to sleep. Subsystem power manager 712 may send a DDR_vote having a value “0” to client active aggregator hardware module 726.

In response to the above step(s), all of the clients associated with CPU subsystem 702 and modem subsystem 704 may be in a sleep mode. At block 731, exit latency vote aggregator hardware module 128 may check the aggregated exit latency values and determine the minimum exit latency. In this example, the exit latency vote from modem subsystem 704 comprises the fourth exit latency vote (EL4) having the value “11”, which is mapped to a power optimized mode. The exit latency vote from CPU subsystem 702 comprises the third exit latency vote (EL3) having the value “10”, which is mapped to the power friendly mode. In this particular example, exit latency vote aggregator hardware module 128 may read these values and determine that the exit latency value of “10” comprises a minimum exit latency. Because the minimum exit latency value of “10” corresponds to the power friendly mode, at block 732, micro-idle power manager hardware system 120 programs DDR controller 118 and DDR PHY 414 to enter the power friendly mode.

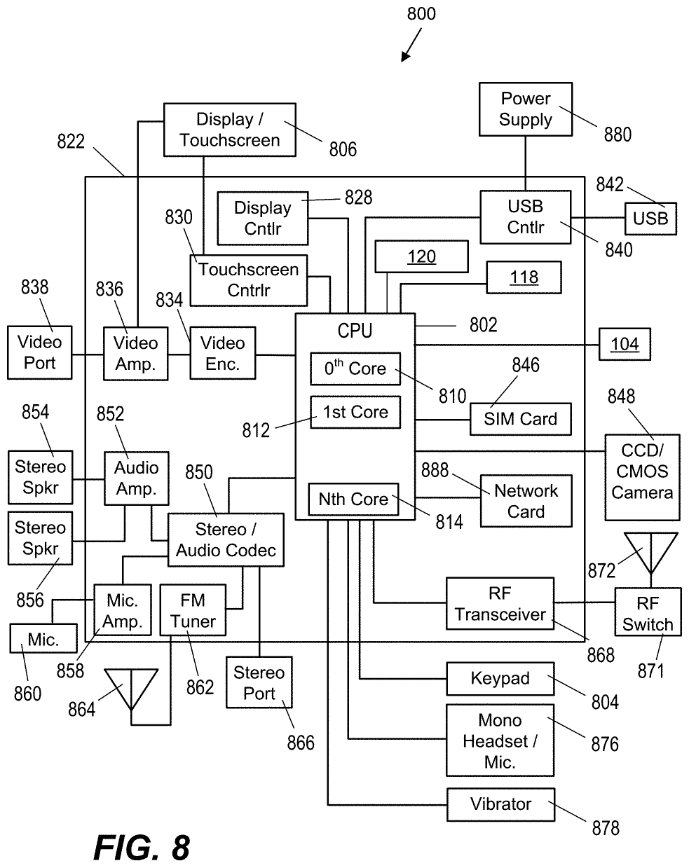

As mentioned above, the system 100 may be incorporated into any desirable computing system. FIG. 8 illustrates the system 100 incorporated in an exemplary portable communication device (PCD) 800. It will be readily appreciated that certain components of the system 100 may be included on the SoC 822 (e.g., micro-idle power manager hardware system 120 and DDR controller 118) while other components (e.g., DRAM 104) may be external components coupled to the SoC 822. The SoC 822 may include a multicore CPU 802. The multicore CPU 802 may include a zeroth core 810, a first core 812, and an Nth core 814. One of the cores may comprise, for example, a graphics processing unit (GPU) with one or more of the others comprising the CPU 802.

A display controller 828 and a touch screen controller 830 may be coupled to the CPU 802. In turn, the touch screen display 806 external to the on-chip system 822 may be coupled to the display controller 828 and the touch screen controller 830.

FIG. 8 further shows that a video encoder 834, e.g., a phase alternating line (PAL) encoder, a sequential color a memoire (SECAM) encoder, or a national television system(s) committee (NTSC) encoder, is coupled to the multicore CPU 802. Further, a video amplifier 836 is coupled to the video encoder 834 and the touch screen display 806. Also, a video port 838 is coupled to the video amplifier 836. As shown in FIG. 8, a universal serial bus (USB) controller 840 is coupled to the multicore CPU 802. Also, a USB port 842 is coupled to the USB controller 840.

Further, as shown in FIG. 8, a digital camera 848 may be coupled to the multicore CPU 802. In an exemplary aspect, the digital camera 848 is a charge-coupled device (CCD) camera or a complementary metal-oxide semiconductor (CMOS) camera.

A stereo audio coder-decoder (CODEC) 850 may be coupled to the multicore CPU 802. Moreover, an audio amplifier 852 may be coupled to the stereo audio CODEC 850. In an exemplary aspect, a first stereo speaker 854 and a second stereo speaker 856 are coupled to the audio amplifier 852. FIG. 8 shows that a microphone amplifier 858 may be also coupled to the stereo audio CODEC 850. Additionally, a microphone 860 may be coupled to the microphone amplifier 858. In a particular aspect, a frequency modulation (FM) radio tuner 862 may be coupled to the stereo audio CODEC 750. Also, an FM antenna 864 is coupled to the FM radio tuner 862. Further, stereo headphones 866 may be coupled to the stereo audio CODEC 850.

FIG. 8 further illustrates that a radio frequency (RF) transceiver 868 may be coupled to the multicore CPU 802. An RF switch 870 may be coupled to the RF transceiver 868 and an RF antenna 872. A keypad 804 may be coupled to the multicore CPU 802. Also, a mono headset with a microphone 876 may be coupled to the multicore CPU 802. Further, a vibrator device 878 may be coupled to the multicore CPU 802.

FIG. 8 also shows that a power supply 880 may be coupled to the on-chip system 822. In a particular aspect, the power supply 880 is a direct current (DC) power supply that provides power to the various components of the PCD 800 that require power. Further, in a particular aspect, the power supply is a rechargeable DC battery or a DC power supply that is derived from an alternating current (AC) to DC transformer that is connected to an AC power source.

FIG. 8 further indicates that the PCD 800 may also include a network card 888. The network card 888 may be a Bluetooth network card, a WiFi network card, a personal area network (PAN) card, a personal area network ultra-low-power technology (PeANUT) network card, a television/cable/satellite tuner, or any other network card well known in the art. Further, the network card 888 may be incorporated into a chip, i.e., the network card 888 may be a full solution in a chip, and may not be a separate network card 888.

As depicted in FIG. 8, the touch screen display 806, the video port 838, the USB port 842, the camera 848, the first stereo speaker 854, the second stereo speaker 856, the microphone 860, the FM antenna 864, the stereo headphones 866, the RF switch 870, the RF antenna 872, the keypad 874, the mono headset 876, the vibrator 878, and the power supply 880 may be external to the on-chip system 822.

It should be appreciated that one or more of the method steps described herein may be stored in the memory as computer program instructions, such as the modules described above. These instructions may be executed by any suitable processor in combination or in concert with the corresponding module to perform the methods described herein.

Certain steps in the processes or process flows described in this specification naturally precede others for the invention to function as described. However, the invention is not limited to the order of the steps described if such order or sequence does not alter the functionality of the invention. That is, it is recognized that some steps may performed before, after, or parallel (substantially simultaneously with) other steps without departing from the scope and spirit of the invention. In some instances, certain steps may be omitted or not performed without departing from the invention. Further, words such as “thereafter”, “then”, “next”, etc. are not intended to limit the order of the steps. These words are simply used to guide the reader through the description of the exemplary method.

Additionally, one of ordinary skill in programming is able to write computer code or identify appropriate hardware and/or circuits to implement the disclosed invention without difficulty based on the flow charts and associated description in this specification, for example.

Therefore, disclosure of a particular set of program code instructions or detailed hardware devices is not considered necessary for an adequate understanding of how to make and use the invention. The inventive functionality of the claimed computer implemented processes is explained in more detail in the above description and in conjunction with the Figures which may illustrate various process flows.

In one or more exemplary aspects, the functions described may be implemented in hardware, software, firmware, or any combination thereof. If implemented in software, the functions may be stored on or transmitted as one or more instructions or code on a computer-readable medium. Computer-readable media include both computer storage media and communication media including any medium that facilitates transfer of a computer program from one place to another. A storage media may be any available media that may be accessed by a computer. By way of example, and not limitation, such computer-readable media may comprise RAM, ROM, EEPROM, NAND flash, NOR flash, M-RAM, P-RAM, R-RAM, CD-ROM or other optical disk storage, magnetic disk storage or other magnetic storage devices, or any other medium that may be used to carry or store desired program code in the form of instructions or data structures and that may be accessed by a computer.

Also, any connection is properly termed a computer-readable medium. For example, if the software is transmitted from a website, server, or other remote source using a coaxial cable, fiber optic cable, twisted pair, digital subscriber line (“DSL”), or wireless technologies such as infrared, radio, and microwave, then the coaxial cable, fiber optic cable, twisted pair, DSL, or wireless technologies such as infrared, radio, and microwave are included in the definition of medium.

Disk and disc, as used herein, includes compact disc (“CD”), laser disc, optical disc, digital versatile disc (“DVD”), floppy disk and blu-ray disc where disks usually reproduce data magnetically, while discs reproduce data optically with lasers. Combinations of the above should also be included within the scope of computer-readable media.

Alternative embodiments will become apparent to one of ordinary skill in the art to which the invention pertains without departing from its spirit and scope. Therefore, although selected aspects have been illustrated and described in detail, it will be understood that various substitutions and alterations may be made therein without departing from the spirit and scope of the present invention, as defined by the following claims.

What is claimed is:

1. A method of micro-idle memory power management, the method comprising:
receiving and storing an exit latency vote from each of a plurality of memory subsystems on a system on chip electrically coupled to a system memory;
in response to a micro-idle memory state in which each of the memory subsystems are idle, determining a minimum exit latency value from the plurality of exit latency votes;
selecting one of a plurality of system memory modes having a micro-idle sleep time that meets the minimum exit latency value while minimizing system memory power consumption; and
initiating the selected system memory mode.

2. The method of claim 1, wherein the plurality of exit latency votes are stored in one or more hardware registers.

3. The method of claim 1, wherein each of the plurality of memory subsystems comprises a software driver for transmitting the corresponding exit latency vote.

4. The method of claim 1, wherein the micro-idle memory state comprises each of the memory subsystems on the system on chip providing a sleep signal.

5. The method of claim 1, wherein the plurality of memory subsystems comprise one or more of a central processing unit (CPU), a modem processor, a digital signal processor, and a graphics processing unit (GPU).

6. The method of claim 1, wherein each of the plurality of system memory modes modes are mapped to a distinct numerical range for the micro-idle sleep time.

7. The method of claim 6, wherein a first numerical range comprises a first micro-idle sleep time of approximately 1-20 microseconds, a second numerical range comprises a second micro-idle sleep time of approximately 21-50 microseconds, a third numerical range comprises a third micro-idle sleep time of approximately 50-200 microseconds, and fourth numerical range comprises a fourth micro-idle sleep time exceeding approximately 200 microseconds.

8. The method of claim 1, wherein the system memory comprises double data rate (DDR) memory, and the plurality of system memory modes comprise:
a first system memory mode comprising a maximum memory performance mode having a first predetermined micro-idle sleep time in a first numerical range approximately equal to 1-20 microseconds;
a second system memory mode comprising a first low power memory mode with clock stop power down and having a second predetermined micro-idle sleep time in a second numerical range approximately equal to 21-50 microseconds;
a third low power memory mode comprising a second low power memory mode with the system memory in a self-refresh mode, a system memory controller and corresponding PHY in a low power state, and having a third predetermined micro-idle sleep time in a third numerical range approximately equal to 51-200 microseconds; and
a fourth low power memory mode comprising a third low power memory mode with the system memory in the self-refresh mode, the system memory controller and the corresponding PHY in a power-collapsed state, and having a fourth predetermined micro-idle sleep time in a fourth numerical range above approximately 200 microseconds.

9. A micro-idle memory power management system comprising:
means for receiving and storing an exit latency vote from each of a plurality of memory subsystems on a system on chip electrically coupled to a system memory;
means for determining, in response to a micro-idle memory state in which each of the memory subsystems are idle, a minimum exit latency value from the plurality of exit latency votes;
means for selecting one of a plurality of system memory modes having a micro-idle sleep time that meets the minimum exit latency value while minimizing system memory power consumption; and
means for initiating the selected system memory mode.

10. The system of claim 9, wherein the means for receiving and storing the plurality of exit latency votes comprise one or more hardware registers.

11. The system of claim 9, wherein the micro-idle memory state comprises each of the memory subsystems on the system on chip providing a sleep signal.

12. The system of claim 9, wherein the plurality of memory subsystems comprise one or more of a central processing unit (CPU), a modem processor, a digital signal processor, and a graphics processing unit (GPU).

13. The system of claim 9, wherein each of the plurality of system memory modes modes are mapped to a distinct numerical range for the micro-idle sleep time.

14. The system of claim 13, wherein a first numerical range comprises a first micro-idle sleep time of approximately 1-20 microseconds, a second numerical range comprises a second micro-idle sleep time of approximately 21-50 microseconds, a third numerical range comprises a third micro-idle sleep time of approximately 50-200 microseconds, and fourth numerical range comprises a fourth micro-idle sleep time exceeding approximately 200 microseconds.

15. The system of claim 9, wherein the system memory comprises double data rate (DDR) memory, and the plurality of system memory modes comprise:
a first system memory mode comprising a maximum memory performance mode having a first predetermined micro-idle sleep time in a first numerical range approximately equal to 1-20 microseconds;
a second system memory mode comprising a first low power memory mode with clock stop power down and having a second predetermined micro-idle sleep time in a second numerical range approximately equal to 21-50 microseconds;
a third low power memory mode comprising a second low power memory mode with the system memory in a self-refresh mode, a system memory controller and corresponding PHY in a low power state, and having a third predetermined micro-idle sleep time in a third numerical range approximately equal to 51-200 microseconds; and
a fourth low power memory mode comprising a third low power memory mode with the system memory in the self-refresh mode, the system memory controller and the corresponding PHY in a power-collapsed state, and having a fourth predetermined micro-idle sleep time in a fourth numerical range above approximately 200 microseconds.

16. A micro-idle memory power management system comprising:
a first hardware component configured to receive and store an exit latency vote from each of a plurality of memory subsystems on a system on chip electrically coupled to a system memory;
a second hardware component configured to determine, in response to a micro-idle memory state in which each of the memory subsystems are idle, a minimum exit latency value from the plurality of exit latency votes;
a third hardware component configured to select one of a plurality of system memory modes having a micro-idle sleep time that meets the minimum exit latency value while minimizing system memory power consumption; and
a fourth hardware component configured to initiate the selected system memory mode.

17. The micro-idle memory power management system of claim 16, wherein the first hardware component comprises one or more hardware registers.

18. The micro-idle memory power management system of claim 16, wherein the first hardware component receives the exit latency vote from a dedicated software driver associated with each of the memory subsystems.

19. The micro-idle memory power management system of claim 16, wherein the micro-idle memory state comprises each of the memory subsystems on the system on chip providing a sleep signal.

20. The micro-idle memory power management system of claim 16, wherein the plurality of memory subsystems comprise one or more of a central processing unit (CPU), a modem processor, a digital signal processor, and a graphics processing unit (GPU).

21. The micro-idle memory power management system of claim 16, wherein the second hardware component comprises a comparator in communication with the first hardware component and configured to determine, in response to a micro-idle memory state in which each of the plurality of memory subsystems are idle, a minimum exit latency value from the plurality of exit latency votes.

22. The micro-idle memory power management system of claim 16, wherein the third hardware component comprises a finite state machine.

23. The micro-idle memory power management system of claim 16, wherein each of the plurality of system memory modes are mapped to a distinct numerical range for the micro-idle sleep time.

24. The micro-idle memory power management system of claim 23, wherein a first numerical range comprises a first micro-idle sleep time of approximately 1-20 microseconds, a second numerical range comprises a second micro-idle sleep time of approximately 21-50 microseconds, a third numerical range comprises a third micro-idle sleep time of approximately 50-200 microseconds, and fourth numerical range comprises a fourth micro-idle sleep time exceeding approximately 200 microseconds.

25. The micro-idle memory power management system of claim 16, wherein the system memory comprises double data rate (DDR) memory, and the plurality of system memory modes comprise:
a first system memory mode comprising a maximum memory performance mode having a first predetermined micro-idle sleep time in a first numerical range approximately equal to 1-20 microseconds;
a second system memory mode comprising a first low power memory mode with clock stop power down and having a second predetermined micro-idle sleep time in a second numerical range approximately equal to 21-50 microseconds;
a third low power memory mode comprising a second low power memory mode with the system memory in a self-refresh mode, a system memory controller and corresponding PHY in a low power state, and having a third predetermined micro-idle sleep time in a third numerical range approximately equal to 51-200 microseconds; and
a fourth low power memory mode comprising a third low power memory mode with the system memory in the self-refresh mode, the system memory controller and the corresponding PHY in a power-collapsed state, and having a fourth predetermined micro-idle sleep time in a fourth numerical range above approximately 200 microseconds.

26. A micro-idle memory power management system comprising:
a double data rate (DDR) memory electrically coupled to a system on chip (SoC);
the SoC comprising a plurality of memory subsystems, a DDR memory controller, and a micro-idle power management hardware module; and
the micro-idle power management hardware module comprising:
one or more hardware registers configured to receive and store an exit latency vote from each of the plurality of memory subsystems;
a comparator in communication with the one or more hardware registers and configured to determine, in response to a micro-idle memory state in which each of the plurality of memory subsystems are idle, a minimum exit latency value from the plurality of exit latency votes;
a finite state machine comprising a plurality of memory states and configured to receive the minimum exit latency and, in response, select one of the plurality of memory states having a micro-idle sleep time that meets the minimum exit latency value while minimizing DDR memory power consumption.

27. The micro-idle memory power management system of claim 26, wherein each of the plurality of memory states are mapped to a distinct numerical range for the micro-idle sleep time.

28. The micro-idle memory power management system of claim 27, wherein a first numerical range comprises a first micro-idle sleep time of approximately 1-20 microseconds, a second numerical range comprises a second micro-idle sleep time of approximately 21-50 microseconds, a third numerical range comprises a third micro-idle sleep time of approximately 50-200 microseconds, and fourth numerical range comprises a fourth micro-idle sleep time exceeding approximately 200 microseconds.

29. The micro-idle memory power management system of claim 26, wherein the plurality of memory states comprise:
a first memory state comprising a maximum memory performance mode having a first predetermined micro-idle sleep time in a first numerical range approximately equal to 1-20 microseconds;
a second memory state comprising a first low power memory mode with clock stop power down and having a second predetermined micro-idle sleep time in a second numerical range approximately equal to 21-50 microseconds;
a third low power memory state comprising a second low power memory mode with the system memory in a self-refresh mode, a system memory controller and corresponding PHY in a low power state, and having a third predetermined micro-idle sleep time in a third numerical range approximately equal to 51-200 microseconds; and
a fourth low power memory state comprising a third low power memory mode with the system memory in the self-refresh mode, the system memory controller and the corresponding PHY in a power-collapsed state, and having a fourth predetermined micro-idle sleep time in a fourth numerical range above approximately 200 microseconds.

30. The micro-idle memory power management system of claim 26, wherein the plurality of memory subsystems comprise one or more of a central processing unit (CPU), a modem processor, a digital signal processor, and a graphics processing unit (GPU) with a corresponding software driver configured to transmit the corresponding exit latency vote to the micro-idle power management hardware module.
